(19) United States
(12) Patent Application Publication
(10) Pub. No.: US 2017/0133614 A1
(43) Pub. Date: May 11, 2017

(54) Light-Emiting Device and Manufacturing Method Therefor, Display Apparatus, and Optical Detection Apparatus

(71) Applicant: BOE TECHNOLOGY GROUP CO., LTD., Beijing (CN)

(72) Inventors: JINGXIA GU, Beijing (CN); Shi SHU, Beijing (CN); Zhi jun LV, Beijing (CN); Feng Zhang, Beijing (CN)

(21) Appl. No.: 15/320,916

(22) PCT Filed: Apr. 16, 2015
(86) PCT No.: PCT/CN2015/076723

§ 371 Date: Dec. 21, 2016

(30) Foreign Application Priority Data
Dec. 1, 2014 (CN) 201410718023.6

(51) Int. Cl. H01L 51/50; H01L 27/28; H01L 51/56; H01L 51/00; H01L 51/52

(52) U.S. Cl. CPC H01L 51/502; H01L 51/0096; H01L 51/5206; H01L 51/5088; H01L 51/5056; H01L 51/5072; H01L 51/5221; H01L 51/56; H01L 27/288; Y10S 977/774; Y10S 977/814; Y10S 977/819; Y10S 977/818; Y10S 977/824; Y10S 977/95; B82Y 20/00

(57) ABSTRACT

A light-emitting device and a manufacturing method therefor, a display apparatus comprising the light-emitting device, and an optical detection apparatus comprising the light-emitting device. The light-emitting device includes a substrate, and an anode, a hole injection layer, a hole-transmission layer, a light emitting layer, an electron transmission layer, and a cathode sequentially stacked on the substrate. The material for forming the hole-transmission layer and/or the electron transmission layer includes a photoconductive high polymer material.

### TECHNICAL FIELD

Embodiments of the present invention relate to a light emitting device and a fabricating method thereof as well as a display device and a photodetecting device.

### BACKGROUND

Organic light-emitting diode (OLED) display devices have advantages such as self-illumination, high contrast, small thickness, large visual angle, fast response, use in a flexible panel, large applicable range of temperature, simple configuration and fabricating process and the like, and have become one of the mainstream developing directions of existing technologies for flat panel displays.

An OLED display device mainly includes a TFT (Thin Film Transistor) array substrate and OLED light emitting devices disposed thereon. The structure of an OLED light emitting device consists of an anode, a hole injection layer, a hole transport layer, a light emitting layer, an electron transport layer and a cathode that are sequentially stacked together. When a voltage is applied across an OLED light emitting device, holes in the anode are injected into the light emitting layer via the hole injection layer and the hole transport layer, and electrons in the cathode are injected into the light emitting layer via the electron transport layer, so that the holes and the electrons meet and recombine in the light emitting layer, resulting in excitons which, when excited in the light emitting layer, will radiate photons outward, enabling the device to illuminate.

### SUMMARY

Embodiments of the present invention provide a light emitting device comprising, a substrate; and an anode, a hole injection layer, a hole transport layer, a light emitting layer, an electron transport layer, and a cathode sequentially stacked on the substrate, wherein a material of the hole transport layer and/or the electron transport layer comprises a photoconductive polymer material.

In one embodiment of the present invention, for example, the material of the hole transport layer comprises the photoconductive polymer material, and the photoconductive polymer material of the hole transport layer comprises a P-type photoconductive polymer material.

In one embodiment of the present invention, for example, the material of the hole transport layer comprises the photoconductive polymer material, and the photoconductive polymer material of the hole transport layer comprises poly-N-vinylcarbazole (PVK) or derivative thereof, phthalocyanine or polymer thereof, or azo-polymer.

In one embodiment of the present invention, for example, the material of the electron transport layer comprises the photoconductive polymer material, and the photoconductive polymer material of the electron transport layer comprises an N-type photoconductive polymer material.

In one embodiment of the present invention, for example, the material of the electron transport layer comprises inorganic nanocrystals.

In one embodiment of the present invention, for example, the inorganic nanocrystals comprise ZnO nanocrystals.

In one embodiment of the present invention, for example, a material of the light emitting layer comprises a quantum-dot material.

In one embodiment of the present invention, for example, the quantum-dot material comprises semiconductor nanocrystals coated with a coating layer.

In one embodiment of the present invention, for example, the semiconductor nanocrystals comprises at least one selected from the group consisting of Si, C, InAs, InP, GaAs, CdS, CdSe or CdTe.

Embodiments of the present invention provide a fabricating method of a light emitting device, comprising, sequentially providing an anode, a hole injection layer, a hole transport layer, a light emitting layer, an electron transport layer and a cathode on a substrate, wherein the hole transport layer and/or the electron transport layer is formed of a photoconductive polymer material.

In one embodiment of the present invention, for example, the fabricating method further comprising: forming the light emitting layer using a quantum-dot material.

Embodiments of the present invention provide a display device comprising the above described light emitting device.

Embodiments of the present invention provide a photodetecting device comprising the above described light emitting device.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 is a planar structural diagram of a display device provided in an embodiment of the present invention; and

FIG. 2 is a cross-sectional view along plane A-A in FIG. 1.

### DETAILED DESCRIPTION

In order to make objects, technical details and advantages of the embodiments of the disclosure apparent, the technical solutions of the embodiment will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

An embodiment of the present invention provides a light emitting device, which, as shown in FIG. 2, includes a substrate 1 and an anode 2, a hole injection layer 3, a hole transport layer 4, a light emitting layer 5, an electron transport layer 6, and a cathode 7 that are sequentially stacked on the substrate 1, wherein a material of the hole transport layer 4 and/or the electron transport layer 6 comprises a photoconductive polymer material.

In the light emitting device provided in the present embodiment, the hole transport layer and/or the electron transport layer are formed with a photoconductive polymer material, which can improve the carrier transport efficiency of the hole transport layer and/or the electron transport layer so as to increase the light emitting efficiency of the light emitting device, because the photoconductive polymer material, when exposed to light excitation, can generate and facilitate transfer of carriers.

In the case of materials of the hole transport layer 4 comprising the photoconductive polymer material, the photoconductive polymer material that is comprised in the hole transport layer 4 may be a P-type photoconductive polymer material, which, when exposed to light, generates holes as carriers and thus can improve hole transport efficiency.

At this point, for example, the photoconductive polymer material included in the hole transport layer 4 may comprise at least one selected from the group consisting of poly-N-vinylcarbazole (PVK) and derivatives thereof, phthalocyanine and polymers thereof, azo-polymers or the like, and for example are PVK and derivatives thereof. PVK is obtained through polymerization of N-vinylcarbazole monomers and has electroluminescence properties with an electroluminescence peak at 412 nm. PVK has a strong transport capacity for holes, which can improve light emitting efficiency of the device through cooperativity, and in addition PVK is of high robustness against heat, dilute acid and dilute base, which improves the stability of the device.

In the case of a material of the electron transport layer 6 comprising a photoconductive polymer material, the photoconductive polymer material that is comprised in the electron transport layer 6 may be an N-type photoconductive polymer material, which, when exposed to light excitation, generates electrons as carriers and thus can improve electron transport efficiency.

In other embodiments of the present invention, for example, the material of the electron transport layer 6 may comprise inorganic nanocrystals, such as ZnO nanocrystals, to further improve light emission efficiency of the device.

Based on the technical solutions described above, the materials of the light emitting layer 5 of the light emitting device in the present embodiment may be selected from fluorescent materials, phosphorescent materials or quantum-dot materials emitting light of different colors, or any combination thereof. For example, quantum-dot materials are used in one embodiment of the present invention. Quantum-dot materials have unique photoluminescence and electroluminescence properties due to their quantum size effect and dielectric confinement effect, and as a result can be used for the light emitting layer of a light emitting device. Compared with a conventional light emitting device using fluorescent materials, the light emitting device provided in the present invention further improves light emission efficiency by using quantum-dot materials to form a light emitting layer with high light emission efficiency.

In addition, the quantum-dot light emitting device exhibits advantages such as high photochemical stability, insensitive to photodecomposition, wide range excitation, narrow range emission, high colorimetric purity and the like. Also, in an application using quantum-dot materials, there is no need to select different fluorescent materials to satisfy different requirements for color of light emission, and the color of light emission can be changed only by controlling the size or composition of the quantum-dot materials to regulate the luminescent spectrum of the light emitting device (from the near infrared zone to the ultraviolet zone).

In the present embodiment, the quantum-dot materials included in the materials of the light emitting layer 5 may be semiconductor nanocrystals coated with a coating layer, and for example are at least one of materials formed from IV group elements such as Si, C or the like, materials formed from III group and V group elements such as InAs, InP, GaAs, or the like, and materials formed from II group and VI group elements such as CdS, CdSe, CdTe or the like, coated with a coating layer. The diameters of the quantum dots in the light emitting layer 5 may be, for example, from 2 nm to 10 nm to further improve quantum yield and luminous efficiency of the device.

The present embodiment further provides a method of fabricating a light emitting device corresponding to the light emitting device provided in the embodiment, the method including the step of forming a hole transport layer and/or an electron transport layer using photoconductive polymer materials, which can improve light emission efficiency of the fabricated light emitting device utilizing the property of the photoconductive polymer materials of generating carriers under light excitation.

Furthermore, the fabricating method provided in the present embodiment further includes forming a light emitting layer with quantum-dot materials to further improve the light emission efficiency of the fabricated light emitting device utilizing high light emission efficiency of the quantum-dot materials.

Take a bottom emitting type light emitting device for example, an embodiment of the present invention provides a process for fabricating a light emitting device as described in the following.

A substrate 1 is provided, which may be selected from a transparent glass substrate, a quartz substrate and the like. Or, if the light emitting device to be fabricated is a flexible device, the substrate 1 may be made of flexible base materials, such as PET (polyethylene terephthalate), PEN (polyethylene naphthalate) or the like. ITO (Indium Tin Oxide) is deposited on the substrate 1 to form an anode 2. PEDOT:PSS solution is spin-coated on the anode 2 to form a hole injection layer 3. Chloroformic solution of PVK is applied on the hole injection layer 3 by spin coating, ink jetting or other processes and then baked and cooled to form a hole transport layer 4. Quantum-dot solution (with methylbenzene, chloroform or the like as solvent) is applied on the hole injection layer 3 by spin coating, ink jetting, printing or other processes to form a light emitting layer 5. ZnO nanocrystals are spin-coated on the light emitting layer 5 to form an electron transport layer 6. Finally, Al is evaporated on the electron transport layer 6 to form a cathode.

It should be noted that the materials and the technologies used to fabricate individual layers of film of the light emitting device are not limited to those in the fabricating process of a light emitting device as described above, and can be chosen depending on practical considerations in other embodiments of the present invention.

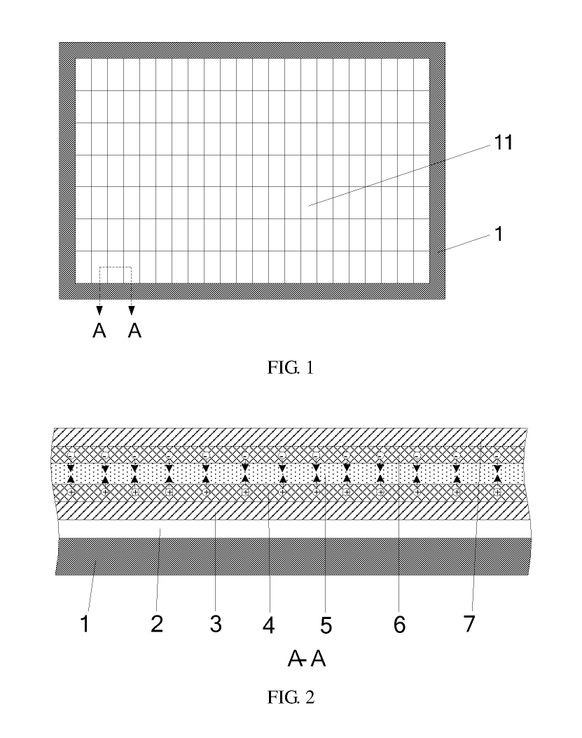

The present embodiment further provides a display device, which includes the light emitting device provided in the embodiment. As shown in FIGS. 1 and 2, the display device comprises a substrate 1 and a plurality of pixels 11 arranged in a matrix on the substrate 1, each pixel including a light emitting device, wherein FIG. 1 is a planar structural diagram of the display device and FIG. 2 is a cross-sectional view of the display device illustrating the cross-sectional configuration of the light emitting device in each pixel of the display device. Each pixel may further comprise addressing or driving elements such as thin film transistors as well as auxiliary elements such as capacitors as required. The display device provided in the present embodiment also has the advantages of high light emitting efficiency and high display brightness by using the light emitting device provided in the embodiment.

In addition, since high polymer photoconductors have the characteristics of good film forming ability, easy processing and molding, and good flexibility, the light emitting device provided in the present embodiment have high-quality layers of film and better performance, can be fabricated in a simpler process and more applicable in fabrication of a flexible display device.

It should be noted that in the display device provided in the present embodiment the substrate may be, for example, a thin film transistor array substrate including thin film transistors disposed in one to one correspondence with pixels of the display device. For example, the thin film transistor in each pixel has it drain connected to the anode of the light emitting device so as to driving the corresponding light emitting device to emit light.

The present embodiment further provides a photodetecting device, which comprises the light emitting device provided in the embodiment. As shown in FIG. 2, the light emitting device comprises a substrate 1 and an anode 2, a hole injection layer 3, a hole transport layer 4, a light emitting layer 5, an electron transport layer 6 and a cathode 7 that are stacked sequentially on the substrate 1, wherein the materials used to form the hole transport layer 4 and/or electron transport layer 6 comprise photoconductive polymer materials. Sine different photoconductive polymer materials differ in sensitivity to light radiation, for example, as photoconductive polymer materials, poly-N-vinylcarbazole (PVK) and derivatives thereof, phthalocyanine and derivatives thereof, azo-polymers and the like are different in optical band required to achieve the maximum carrier transport rate, corresponding photoconductive polymer materials can be selected for the transport layer of the light emitting device according to the actual optical band to be detected, so that depending on the final luminance of the light emitting device detection for different optical bands can be achieved and the range can be expanded to the whole band of visible light.

The above are only the model implementation ways of the present disclosure, and not used to limit the scope of protection of the present disclosure, the scope of protection of the present disclosure is determined by the attached claims.

The present application claims the priority of the Chinese Patent Application No. 201410718023.6 filed on Dec. 1, 2014, which is incorporated herein by reference as part of the disclosure of the present application.

1. A light emitting device comprising,
a substrate; and
an anode, a hole injection layer, a hole transport layer, a light emitting layer, an electron transport layer, and a cathode sequentially stacked on the substrate,
wherein a material of the hole transport layer and/or the electron transport layer comprises a photoconductive polymer material.

2. The light emitting device of claim 1, wherein the material of the hole transport layer comprises the photoconductive polymer material, and the photoconductive polymer material of the hole transport layer comprises a P-type photoconductive polymer material.

3. The light emitting device of claim 1, wherein the material of the hole transport layer comprises the photoconductive polymer material, and the photoconductive polymer material of the hole transport layer comprises poly-N-vinylcarbazole (PVK) or derivative thereof, phthalocyanine or polymer thereof, or azo-polymer.

4. The light emitting device of claim 1, wherein the material of the electron transport layer comprises the photoconductive polymer material, and the photoconductive polymer material of the electron transport layer comprises an N-type photoconductive polymer material.

5. The light emitting device of claim 1, wherein the material of the electron transport layer comprises inorganic nanocrystals.

6. The light emitting device of claim 5, wherein the inorganic nanocrystals comprise ZnO nanocrystals.

7. The light emitting device of claim 1, wherein a material of the light emitting layer comprises a quantum-dot material.

8. The light emitting device of claim 7, wherein the quantum-dot material comprises semiconductor nanocrystals coated with a coating layer.

9. The light emitting device of claim 8, wherein the semiconductor nanocrystals comprises at least one selected from the group consisting of Si, C, InAs, InP, GaAs, CdS, CdSe or CdTe.

10. A fabricating method of a light emitting device, comprising,
sequentially providing an anode, a hole injection layer, a hole transport layer, a light emitting layer, an electron transport layer and a cathode on a substrate,
wherein the hole transport layer and/or the electron transport layer is formed of a photoconductive polymer material.

11. The fabricating method of claim 10, further comprising: forming the light emitting layer using a quantum-dot material.

12. A display device comprising the light emitting device of claim 1.

13. A photodetecting device comprising the light emitting device of claim 1.

14. The light emitting device of claim 2, wherein the material of the hole transport layer comprises the photoconductive polymer material, and the photoconductive polymer material of the hole transport layer comprises poly-N-vinylcarbazole (PVK) or derivative thereof, phthalocyanine or polymer thereof, or azo-polymer.

15. The light emitting device of claim 2, wherein the material of the electron transport layer comprises the photoconductive polymer material, and the photoconductive polymer material of the electron transport layer comprises an N-type photoconductive polymer material.

16. The light emitting device of claim 3, wherein the material of the electron transport layer comprises the photoconductive polymer material, and the photoconductive polymer material of the electron transport layer comprises an N-type photoconductive polymer material.

17. The light emitting device of claim 2, wherein the material of the electron transport layer comprises inorganic nanocrystals.

18. The light emitting device of claim 2, wherein a material of the light emitting layer comprises a quantum-dot material.

19. The light emitting device of claim 3, wherein a material of the light emitting layer comprises a quantum-dot material.

20. The light emitting device of claim 4, wherein a material of the light emitting layer comprises a quantum-dot material.
